(19) United States
(12) Patent Application Publication
(10) Pub. No.: US 2021/0065086 A1
(43) Pub. Date: Mar. 4, 2021

(54) SYSTEM AND METHOD FOR FAILURE CURVE ANALYTICS

(71) Applicant: SAP SE, Walldorf (DE)

(72) Inventors: Simon Lee, Castro Valley, CA (US); Rashmi B. Shetty, Fremont, CA (US); Anubhav Bhatia, Sunnyvale, CA (US); Patrick Brose, San Francisco, CA (US); Martin Weiss, San Mateo, CA (US); Lukas Carullo, Redwood City, CA (US); Lauren McMullen, Mountain View, CA (US); Karthik Mohan Mokashi, San Ramon, CA (US)

(21) Appl. No.: 16/707,539

(22) Filed: Dec. 9, 2019

Related U.S. Application Data
(60) Provisional application No. 62/893,651, filed on Aug. 29, 2019.

(51) Int. Cl. G06Q 10/06; G06Q 10/00

(52) U.S. Cl. CPC G06Q 10/06315; G06Q 10/20

(57) ABSTRACT

Techniques for implementing and using failure curve analytics in an equipment maintenance system are disclosed. A method comprises: accessing a failure curve model for an equipment model, the failure curve model being configured to estimate lifetime failure data for the equipment model for different failure modes corresponding to different specific manners in which the equipment model is capable of failing, the lifetime failure data indicating a probability of the equipment model failing in the specific manner of the failure mode; generating first analytical data for a first failure mode of the plurality of failure modes using the failure curve model based on the first failure mode, the first analytical data indicating at least a portion of the lifetime failure data for the equipment model corresponding to the first failure mode; and causing a visualization of the first analytical data to be displayed on a computing device.

### CROSS-REFERENCE TO RELATED APPLICATIONS

This application claims priority to U.S. Provisional Application No. 62/893,651, filed on Aug. 29, 2019, and entitled, “SYSTEM AND METHOD FOR FAILURE CURVE ANALYTICS,” which is hereby incorporated by reference in its entirety as if set forth herein.

### TECHNICAL FIELD

The present application relates generally to the technical field of electrical computer systems, and, in various embodiments, to systems and methods of equipment maintenance using failure curve analytics.

### BACKGROUND

Current solutions for predicting failures in equipment are dependent on sensor data. However, a significant amount of equipment is not instrumented with sensors for providing such data. Data such as mean time between failures (MTBF) metrics are not actionable measures of equipment life span or remaining useful life. As a result, computer systems lack the ability to accurately estimate important analytical data used in maintaining the equipment, such as the probability of failure and the remaining useful life for a particular equipment model. Furthermore, current solutions do not provide user interfaces with interactive visualizations of such analytical data or the ability for users to interactively adjust the granularity of such analytical data to focus the analytical data on a particular mode of failure of a particular equipment model rather than just a general failure of the particular equipment model.

### BRIEF DESCRIPTION OF THE DRAWINGS

Some example embodiments of the present disclosure are illustrated by way of example and not limitation in the figures of the accompanying drawings, in which like reference numbers indicate similar elements.

FIG. 1 is a network diagram illustrating a client-server system, in accordance with some example embodiments.

FIG. 2 is a block diagram illustrating enterprise applications and services in an enterprise application platform, in accordance with some example embodiments.

FIG. 3 is a block diagram illustrating an equipment maintenance system, in accordance with some example embodiments.

FIG. 4 illustrates a graph of a failure curve model for an equipment model, in accordance with some example embodiments.

FIG. 5 illustrates a graphical user interface (GUI) in which a visualization of a probability of failure curve for an equipment model is displayed, in accordance with some example embodiments.

FIG. 6 illustrates a GUI in which another visualization of a probability of failure curve for an equipment model is displayed, in accordance with some example embodiments.

FIG. 7 illustrates visualizations of a hazard function for an equipment model, in accordance with some example embodiments.

FIG. 8 illustrates a GUI in which a user can submit input defining an alert rule for an equipment model, in accordance with some example embodiments.

FIG. 9 is a flowchart illustrating a method of using failure curve analytics in an equipment maintenance system, in accordance with some example embodiments.

FIG. 10 is a flowchart illustrating another method of using failure curve analytics in an equipment maintenance system, in accordance with some example embodiments.

FIG. 11 is a block diagram of an example computer system on which methodologies described herein can be executed, in accordance with some example embodiments.

### DETAILED DESCRIPTION

Example methods and systems for implementing equipment maintenance using failure curve analytics are disclosed. In the following description, for purposes of explanation, numerous specific details are set forth in order to provide a thorough understanding of example embodiments. It will be evident, however, to one skilled in the art that the present embodiments can be practiced without these specific details.

The implementation of the features disclosed herein involves a non-generic, unconventional, and non-routine operation or combination of operations. By applying one or more of the solutions disclosed herein, some technical effects of the system and method of the present disclosure are to generate accurate and granular analytical data for an equipment model that is not instrumented with sensors. Other technical effects will be apparent from this disclosure as well.

The methods or embodiments disclosed herein may be implemented as a computer system having one or more modules (e.g., hardware modules or software modules). Such modules may be executed by one or more hardware processors of the computer system. In some example embodiments, a non-transitory machine-readable storage device can store a set of instructions that, when executed by at least one processor, causes the at least one processor to perform the operations and method steps discussed within the present disclosure.

The details of one or more variations of the subject matter described herein are set forth in the accompanying drawings and the description below. Other features and benefits of the subject matter described herein will be apparent from the description and drawings, and from the claims.

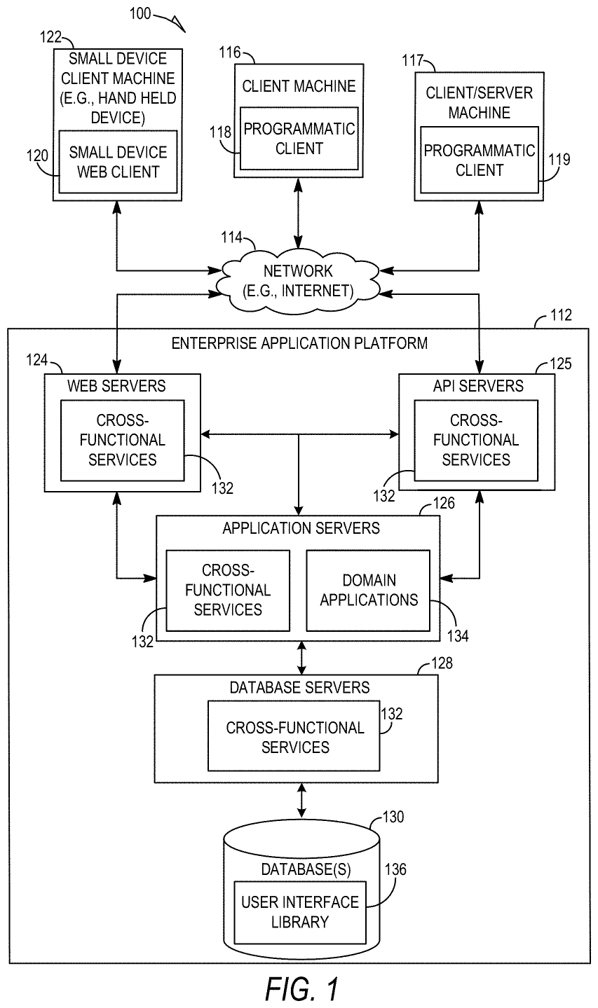

FIG. 1 is a network diagram illustrating a client-server system 100, in accordance with some example embodiments. A platform (e.g., machines and software), in the example form of an enterprise application platform 112, provides server-side functionality, via a network 114 (e.g., the Internet) to one or more clients. FIG. 1 illustrates, for example, a client machine 116 with programmatic client 118 (e.g., a browser), a small device client machine 122 with a small device web client 120 (e.g., a browser without a script engine), and a client/server machine 117 with a programmatic client 119.

Turning specifically to the example enterprise application platform 112, web servers 124 and Application Program Interface (API) servers 125 can be coupled to, and provide web and programmatic interfaces to, application servers 126. The application servers 126 can be, in turn, coupled to one or more database servers 128 that facilitate access to one or more databases 130. The cross-functional services 132 can include relational database modules to provide support services for access to the database(s) 130, which includes a user interface library 136. The web servers 124, API servers 125, application servers 126, and database servers 128 can host cross-functional services 132. The application servers 126 can further host domain applications 134.

The cross-functional services 132 provide services to users and processes that utilize the enterprise application platform 112. For instance, the cross-functional services 132 can provide portal services (e.g., web services), database services and connectivity to the domain applications 134 for users that operate the client machine 116, the client/server machine 117, and the small device client machine 122. In addition, the cross-functional services 132 can provide an environment for delivering enhancements to existing applications and for integrating third-party and legacy applications with existing cross-functional services 132 and domain applications 134. Further, while the system 100 shown in FIG. 1 employs a client-server architecture, the embodiments of the present disclosure are, of course, not limited to such an architecture, and could equally well find application in a distributed, or peer-to-peer, architecture system.

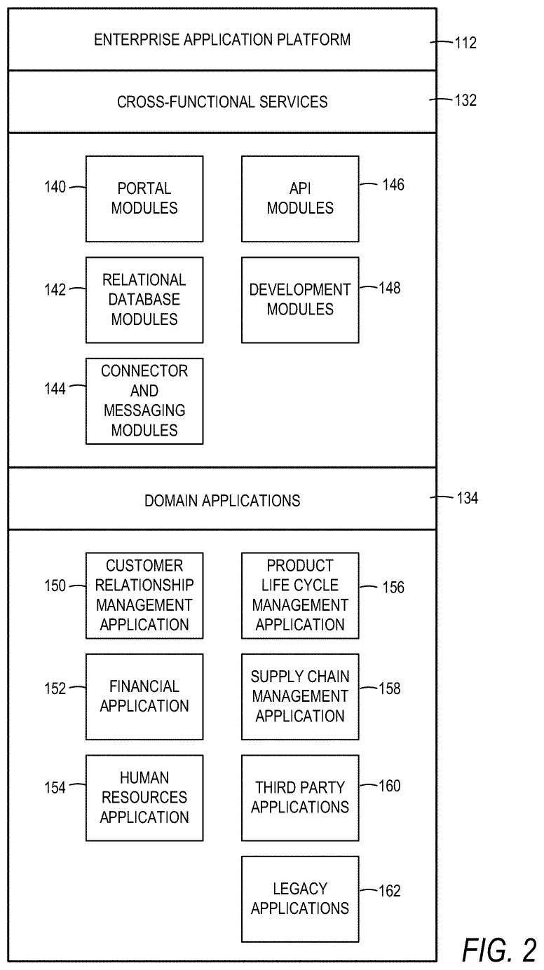

The enterprise application platform 112 can improve (e.g., increase) accessibility of data across different environments of a computer system architecture. For example, the enterprise application platform 112 can effectively and efficiently enable a user to use real data created from use by one or more end users of a deployed instance of a software solution in a production environment when testing an instance of the software solution in the development environment. The enterprise application platform 112 is described in greater detail below in conjunction with FIGS. 2-8.

FIG. 2 is a block diagram illustrating enterprise applications and services in an enterprise application platform 112, in accordance with an example embodiment. The enterprise application platform 112 can include cross-functional services 132 and domain applications 134. The cross-functional services 132 can include portal modules 140, relational database modules 142, connector and messaging modules 144, API modules 146, and development modules 148.

The portal modules 140 can enable a single point of access to other cross-functional services 132 and domain applications 134 for the client machine 116, the small device client machine 122, and the client/server machine 117. The portal modules 140 can be utilized to process, author and maintain web pages that present content (e.g., user interface elements and navigational controls) to the user. In addition, the portal modules 140 can enable user roles, a construct that associates a role with a specialized environment that is utilized by a user to execute tasks, utilize services, and exchange information with other users within a defined scope. For example, the role can determine the content that is available to the user and the activities that the user can perform. The portal modules 140 include a generation module, a communication module, a receiving module and a regenerating module. In addition, the portal modules 140 can comply with web services standards and/or utilize a variety of Internet technologies including JAVA®, J2EE, SAP's Advanced Business Application Programming Language (ABAP®) and Web Dynpro, XML, JCA, JAAS, X.509, LDAP, WSDL, WSRR, SOAP, UDDI and MICROSOFT® .NET®.

The relational database modules 142 can provide support services for access to the database(s) 130, which includes a user interface library 136. The relational database modules 142 can provide support for object relational mapping, database independence, and distributed computing. The relational database modules 142 can be utilized to add, delete, update and manage database elements. In addition, the relational database modules 142 can comply with database standards and/or utilize a variety of database technologies including SQL, SQLDBC, Oracle, MySQL, Unicode, JDBC, or the like.

The connector and messaging modules 144 can enable communication across different types of messaging systems that are utilized by the cross-functional services 132 and the domain applications 134 by providing a common messaging application processing interface. The connector and messaging modules 144 can enable asynchronous communication on the enterprise application platform 112.

The API modules 146 can enable the development of service-based applications by exposing an interface to existing and new applications as services. Repositories can be included in the platform as a central place to find available services when building applications.

The development modules 148 can provide a development environment for the addition, integration, updating, and extension of software components on the enterprise application platform 112 without impacting existing cross-functional services 132 and domain applications 134.

Turning to the domain applications 134, the customer relationship management application 150 can enable access to and can facilitate collecting and storing of relevant personalized information from multiple data sources and business processes. Enterprise personnel that are tasked with developing a buyer into a long-term customer can utilize the customer relationship management applications 150 to provide assistance to the buyer throughout a customer engagement cycle.

Enterprise personnel can utilize the financial applications 152 and business processes to track and control financial transactions within the enterprise application platform 112. The financial applications 152 can facilitate the execution of operational, analytical, and collaborative tasks that are associated with financial management. Specifically, the financial applications 152 can enable the performance of tasks related to financial accountability, planning, forecasting, and managing the cost of finance.

The human resource applications 154 can be utilized by enterprise personnel and business processes to manage, deploy, and track enterprise personnel. Specifically, the human resource applications 154 can enable the analysis of human resource issues and facilitate human resource decisions based on real-time information.

The product life cycle management applications 156 can enable the management of a product throughout the life cycle of the product. For example, the product life cycle management applications 156 can enable collaborative engineering, custom product development, project management, asset management, and quality management among business partners.

The supply chain management applications 158 can enable monitoring of performances that are observed in supply chains. The supply chain management applications 158 can facilitate adherence to production plans and on-time delivery of products and services.

The third-party applications 160, as well as legacy applications 162, can be integrated with domain applications 134 and utilize cross-functional services 132 on the enterprise application platform 112.

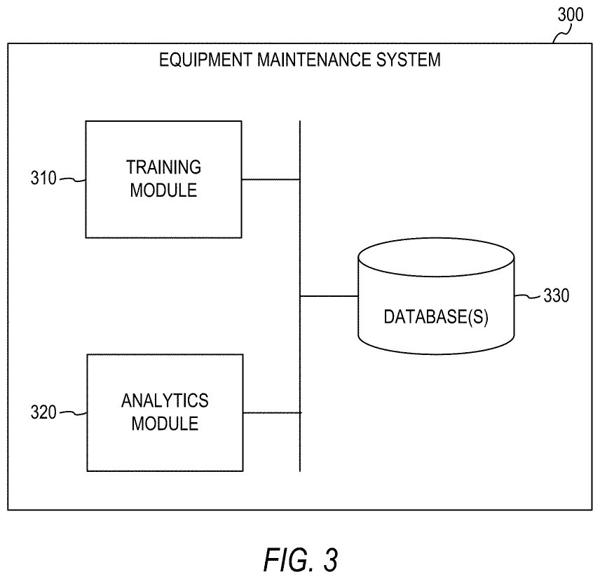

FIG. 3 is a block diagram illustrating an equipment maintenance system 300, in accordance with some example embodiments. In some example embodiments, the equipment maintenance system 300 is configured to automate the collection of maintenance data relating to failure events of an equipment model, and then apply statistical methods of fitting the data to a probability distribution such to determine a failure curve. Based on the failure curve and a life or age indicator of the equipment, the equipment management system 300 can accurately estimate the probability of failure or remaining useful life of the equipment model and enable a user to set an alert rule that can be used by the equipment maintenance system 300 to generate and present alerts based on the alert rule to alert a maintenance team to ensure proper maintenance is performed prior to the equipment being at risk of failing.

In some embodiments, the equipment maintenance system 300 comprises any combination of one or more of a training module 310, an analytics module 320, and one or more database(s) 330. The modules 310 and 320 and the database(s) 330 can reside on a computer system, or other machine, having a memory and at least one processor (not shown). In some embodiments, the modules 310 and 320 is incorporated into the application server(s) 126 in FIG. 1 and the database(s) 330 is incorporated into the database(s) 130 in FIG. 1. However, it is contemplated that other configurations of the modules 310 and 320 and the database(s) 330 are also within the scope of the present disclosure.

In some example embodiments, one or more of the modules 310 and 320 are configured to provide a variety of user interface functionality, such as generating user interfaces, interactively presenting user interfaces to the user, receiving information from the user (e.g., interactions with user interfaces), and so on. Presenting information to the user can include causing presentation of information to the user (e.g., communicating information to a device with instructions to present the information to the user). Information may be presented using a variety of means including visually displaying information and using other device outputs (e.g., audio, tactile, and so forth). Similarly, information may be received via a variety of means including alphanumeric input or other device input (e.g., one or more touch screen, camera, tactile sensors, light sensors, infrared sensors, biometric sensors, microphone, gyroscope, accelerometer, other sensors, and so forth). In some example embodiments, one or more of the modules 310 and 320 are configured to receive user input. For example, one or more of the modules 310 and 320 can present one or more GUI elements (e.g., drop-down menu, selectable buttons, text field) with which a user can submit input. In some example embodiments, one or more of the modules 310 and 320 is configured to perform various communication functions to facilitate the functionality described herein, such as by communicating with a computing device (e.g., the small device client machine 122, the client machine 116, or the client/server machine 117) via the network 114 using a wired or wireless connection.

In some example embodiments, the training module 310 is configured to obtain failure data for an equipment model. The term “equipment model” is used herein to refer to any type of machine that is capable of performing a function and has a unique identification and design that is different from other machines, which may be indicated by a product identification or model number of the equipment model. An equipment model is also referred to herein as an “asset.” The failure data may be stored in and retrieved from the database(s) 330. In some example embodiments, the database(s) 330 stores corresponding failure data for each one of a plurality of equipment models. For example, the database(s) 330 may store corresponding failure data for each one of a plurality of different models of hydraulic pumps, as well as corresponding failure data for each of a plurality of different models of other types or categories of equipment as well.

In some example embodiments, the failure data comprises data identifying, for a specific equipment model, the occurrence of events in which the specific equipment model suffered a functional failure, including data indicating the specific type of failure (e.g., the nature of the failure and the specific subcomponent of the equipment model that suffered the failure) and corresponding time data indicating a time (e.g., the specific day and time of day) at which the failure occurred. The failure data may be based on field failure rate reports that include an itemized reporting of each failure event corresponding to the equipment model. The field failure rate reports can be maintained in the database(s) 330. The failure data may be stored as part of a time series database that is integrated with the equipment maintenance system 300.

The failure data may apply correspond to different physical instances of the same equipment model. For example, an organization may have multiple hydraulic pumps of the same model, and the equipment maintenance system 300 may collect and aggregate all of the data on the failure events for those multiple hydraulic pumps to form the failure data for that specific hydraulic pump model.

Other life or age indicators other than time may also be stored as part of the failure data in order to enable variations on the parameters used for generating analytical data. For example, in addition to indications of failure events being associated with time (e.g., days), indications of failure events may also be associated with other estimators of the real age of an equipment model, such as the number of operations that had been performed by the equipment model at the time the failure event occurred, the amount of matter (e.g., energy, water, oil) that had passed through the equipment model or that was otherwise processed by the equipment model at the time the failure event occurred, the amount of distance (e.g., miles) the equipment model had traveled at the time the failure event occurred, and the amount of a specific type of distance (e.g., city miles versus highway miles) the equipment model had traveled at the time the failure event occurred. Other types of life or age indicators are also within the scope of the present disclosure and may be used in place of time in the example embodiments disclosed herein.

In some example embodiments, the training module 310 is configured to train a failure curve model for the equipment model using the obtained failure data for the equipment model. The failure curve model is configured to estimate lifetime characteristics of assets specific to a particular failure mode. A particular failure mode is a specific manner or way in which a machine may fail, such as with respect to a particular subcomponent of the machine (e.g., radiator leak, dead battery), as opposed to a generalized overall failure of the machine that is not associated with any specific subcomponent of the machine nor any other specific reason for failure. In some example embodiments, the training module 310 estimates lifetime characteristics of assets specific to a particular failure mode using statistical and data driven models. Survival models are used to examine the occurrence of events and establish characteristics of the asset until time of death. Some of the techniques that may be used to assess the lifetime characteristics include, but are not limited to, using parametric, non-parametric and semi-parametric models.

Parametric models use distribution of age history or survival time. Some modeling approaches include, but are not limited to, fitting the age data to Weibull distribution, Exponential Distribution, Goempertz distribution, Gamma distribution, Log-Normal distribution, Log-logistic distribution, Generalized F distribution, and the Coale-McNeil Model. The survival function for parametric models can be mathematically expressed as:

S(t)=Pr(T>t)=1−F(t)=∫ₜ^{∞}ƒ(x)dx,

where S(t) Survival function at age t and ƒ(t) is the probability distribution function (pdf) on the random variable T and F(t) is the cumulative distribution function.

Semi-parametric models assume proportional hazards where covariates are taken into consideration when fitting models. Modeling approaches include, but are not limited to, applying covariates to the parametric families discussed above, accelerated life models, proportional hazard models, such as Cox proportional Hazard Model. With proportional hazard models, there are no assumptions done with regards to the distribution of lifetime data and is assumed to be random. A proportional hazard model can be mathematically expressed as:

h(t,xᵢ,β)=h₀(t)exp(βⁱxᵢ),

where, h₀(t) is the baseline hazard function, that characterizes how the hazard function changes as a function of survival time, Xᵢ is the vector of values of the explanatory variables for the i^{th} asset at time and β is the vector of unknown regression parameters

Non-parametric models make the least amount of assumptions and are often the simplest solution. Examples of non-parametric models include, but are not limited to, an Artificial Neural Network Model and a Markov Chain Monte Carlo survival model.

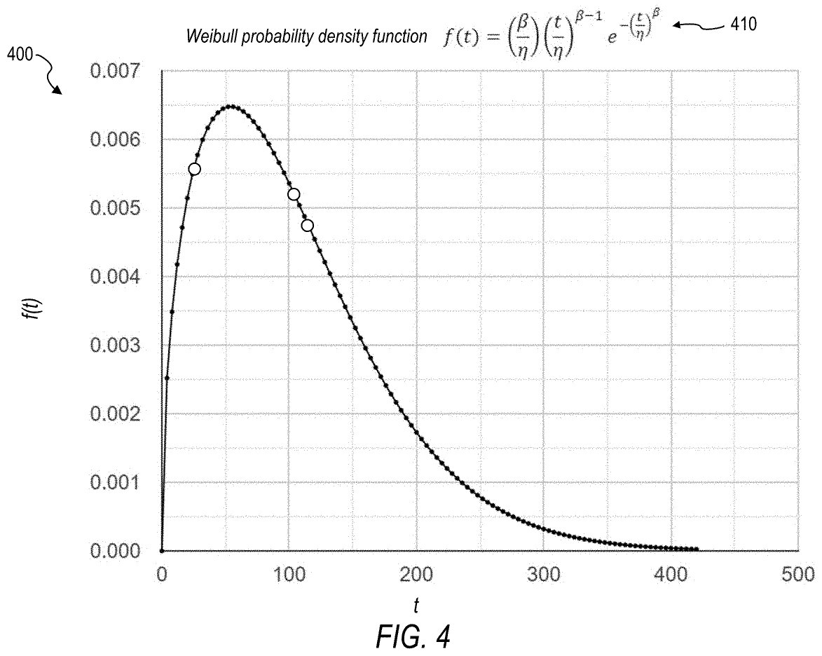

FIG. 4 illustrates a graph 400 of a failure curve model for an equipment model, in accordance with some example embodiments. In some example embodiments, the failure curve model for the equipment model is trained by fitting the failure data for the equipment model to a statistical and data driven model, such as one of the parametric, semi-parametric, or non-parametric models discussed above. For example, the training module 310 may be configured to train the failure curve model for the equipment model by fitting the failure data of the equipment model to the following Weibull probability density function 410, estimating the Weibull shape factor parameter Beta (β) and the Weibull scale factor parameter Eta (η):

$$f ( t ) = ( \frac{β}{η} ) {( \frac{t}{η} )}^{β - 1} {e}^{- {( \frac{t}{η} )}^{β}} .$$

In the formula above, t represents the age factor for the equipment model. Other types of probability distributions, such as exponential and Gaussian, may also be used to train the failure curve model.

In some example embodiments, the analytics module 320 is configured to generate one or more types of analytical data for the equipment model using the failure curve model. Examples of the types of analytical data that may be generated for the equipment model include, but are not limited to, the probability of failure (PoF), the remaining useful life (RUL), and the hazard function. The probability of failure is the probability that the equipment model will suffer a failure event at a particular time or at some other particular life or age indicator (e.g., at a particular number of operations). The remaining useful life is an estimate of the number of remaining years (or some other type of life or age metric) that an item, component, or system is estimated to be able to function in accordance with its intended purpose before needing maintenance, repair, or replacement given a particular time or some other particular life or age indicator. The hazard function (also called the force of mortality, instantaneous failure rate, instantaneous death rate, or age-specific failure rate) is a way to model data distribution in survival analysis and may be used to model an equipment model's chance of failure as a function of its age.

In some example embodiments, the analytics module 320 is configured to cause a visualization of one or more of the types of analytical data for the equipment model to be displayed. The visualization may be generated based on one or more visualization parameters, such as a type of analytics function or a particular failure mode. The type of analytics function defines the type of analytical data that that is to be visualized and displayed, which may include, but is not limited to, the probability of failure (PoF) the remaining useful life (RUL), and the hazard function.

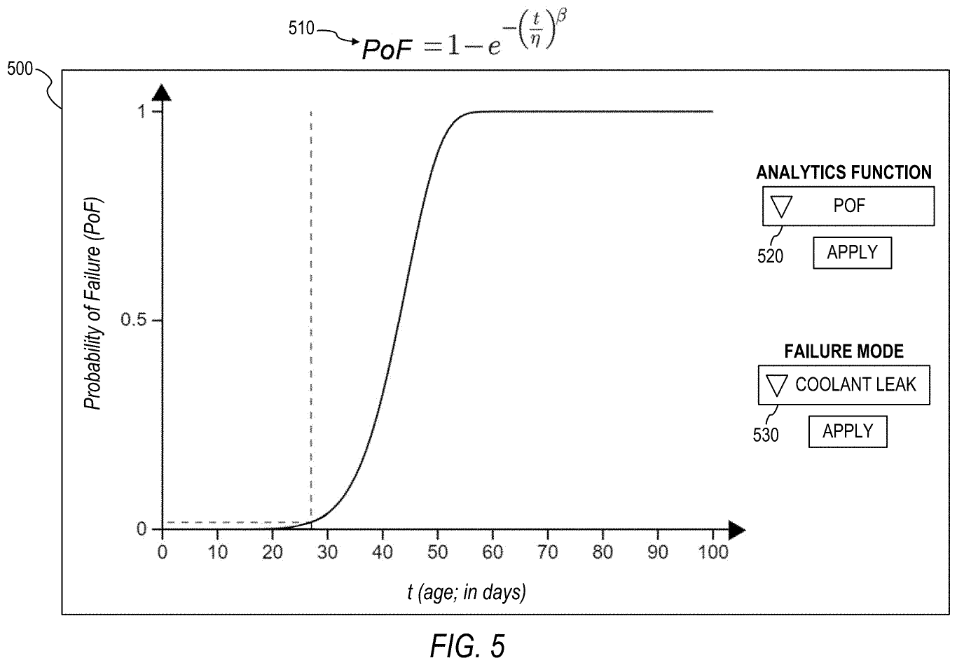

FIG. 5 illustrates a graphical user interface (GUI) 500 in which a visualization of a probability of failure curve for an equipment model is displayed, in accordance with some example embodiments. FIG. 5 shows an example of a probability of failure curve function 510:

$$PoF = 1 - {e}^{- {( \frac{t}{η} )}^{β}} .$$

In some example embodiments, the probability of failure curve is generated based on the following Weibull probability density function:

$${F}_{β , η} ( t ) = \frac{β}{η} {( \frac{t}{η} )}^{β - 1} {e}^{- {( \frac{t}{η} )}^{β}} .$$

However, other functions may be used to generate the probability of failure curve.

In some example embodiments, the probability of failure is visually represented as a percentage (e.g., 50%) or a decimal number (0.5), and the probability of failure is visualized as a function of age (e.g., number of days in operation, number of operations, or other type of age indicator). The user may select (e.g., hover over, click on, or tap on) any part of the visualization to be presented with more detailed information regarding the analytical data of the visualization. For example, the user may select a point on the visualized probability of failure cure that corresponds to 28 days, which may trigger the analytics module 320 to display the corresponding probability of failure for the equipment model at an age of 28 days.

In some example embodiments, the analytics module 320 displays one or more user interface elements 520 configured to enable the user to select the underlying analytics function used for the visualization. For example, the user may use the user interface element 520 to select between probability of failure, remaining useful life, and hazard function as the analytics function to use in generating the visualization. Additionally, in some example embodiments, the analytics module 320 displays one or more user interface elements 530 configured to enable the user to select the failure mode used for the visualization. For example, the user may select between different types of failures (e.g., radiator leak, dead battery) to use in generating the visualization, such that the selection of one type of failure mode (e.g., radiator leak) results in analytical data for that selected type of failure mode being used in a visualization that is displayed to the user, and the selection of another type of failure mode (e.g., dead battery) results in analytical data for that other type of failure mode being used in another visualization that is displayed to the user.

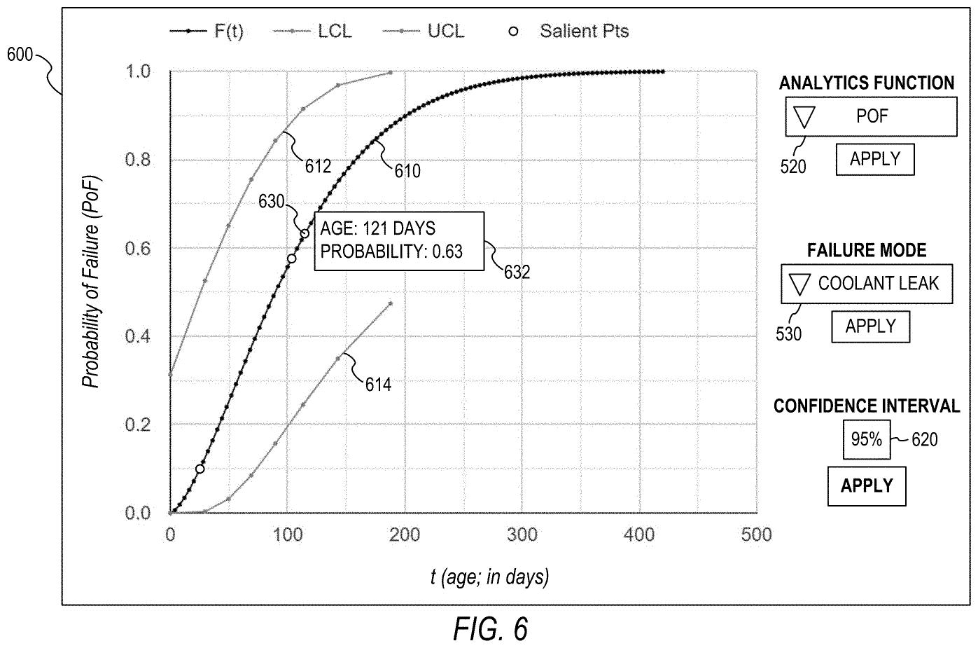

FIG. 6 illustrates a GUI 600 in which another visualization of a probability of failure curve for an equipment model is displayed, in accordance with some example embodiments. In the GUI 600, the analytics module 320 displays one or more user interface elements 620 configured to enable the user to specify a specific probability for a confidence interval to be used in the generation of the visualization of the probability of failure curve. A confidence interval is a range of values so defined that there is a specified probability that the value of a parameter lies within it. For example, by adjusting the probability for the confidence interval using the user interface element 620, the user adjusts the upper and lower bounds of the analytics curve of the visualization. In the example shown in FIG. 6 where the probability of failure curve is visualized as curve 610, the user has specified a probability of 95% for the confidence interval, resulting in the upper bound 612 and lower bound 614 for the curve 610 being generated and displayed. This probability for the confidence interval is able to be adjusted for other types of analytics functions as well, such as for the remaining useful life function. In some example embodiments, the user is able to specify an acceptable probability of failure and the analytics module 320 generates and displays the remaining useful like based on this user-specified probability of failure, where the remaining useful life is the delta between the current age of the equipment model at issue and the age when the probability of failure is estimated to become unacceptable.

In some example embodiments, the analytics module 320 is configured to enable a user to select a point 630 on a curve of a graph displayed as part of a visualization in order to obtain additional data 632 that is specific to that selected point on the curve. For example, in FIG. 6, the analytics module 320 receives a user selection of the point 630 on the curve of the graph and causes the additional data 632 that is specific to the point 630 of the curve to be displayed based on the user selection of the point 630 on the curve.

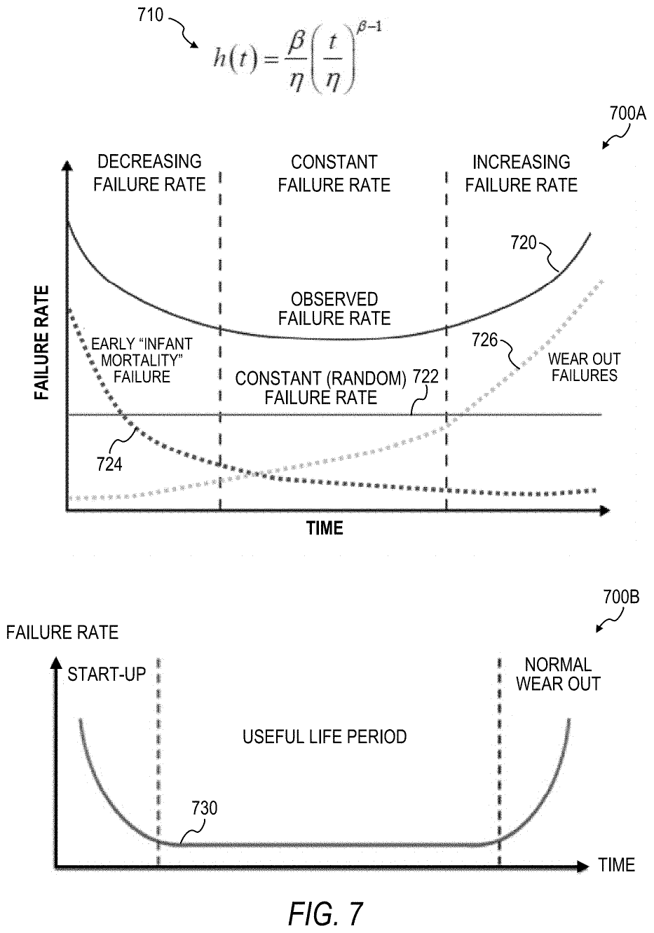

FIG. 7 illustrates visualizations 700A and 700B of a hazard function 710 for an equipment model, in accordance with some example embodiments. The hazard function may be based on a Weibull probability density function and be represented as:

$$h ( t ) = \frac{β}{η} {( \frac{t}{η} )}^{β - 1} .$$

Failure rate over time (e.g., the bathtub curve example) is a hazard function h(t), which may be calculated using the previously discussed Beta β and Eta η. The visualization 700A shows different failure rate curves 720, 722, 724, and 726 corresponding to different types of failure. For example, the failure rate curve 720 represents the overall observed failure rate for the equipment model, the failure rate curve 722 represents the constant (random) failure rate for the equipment model that is attributed to random failures of the equipment model, the failure rate curve 724 represents the early “infant mortality” failure rate for the equipment model that is attributed to early failures of the equipment model (e.g., early failures due to manufacturing defects), and the failure rate curve 726 represents the wear out failure rate for the equipment model that is attributed to failures of the equipment model that are due to normal wear and tear. The visualization 700B shows a curve 730 that is a composite of two or more of the different curves 720, 722, 724, and 726. In some example embodiments, the analytics module 320 displays one or more of the user interface elements 520, 530, and 620 along with the visualizations 700A and 700B, thereby enabling the user to configure the analytics function, failure mode, and confidence interval probability for the visualizations 700A and 700B.

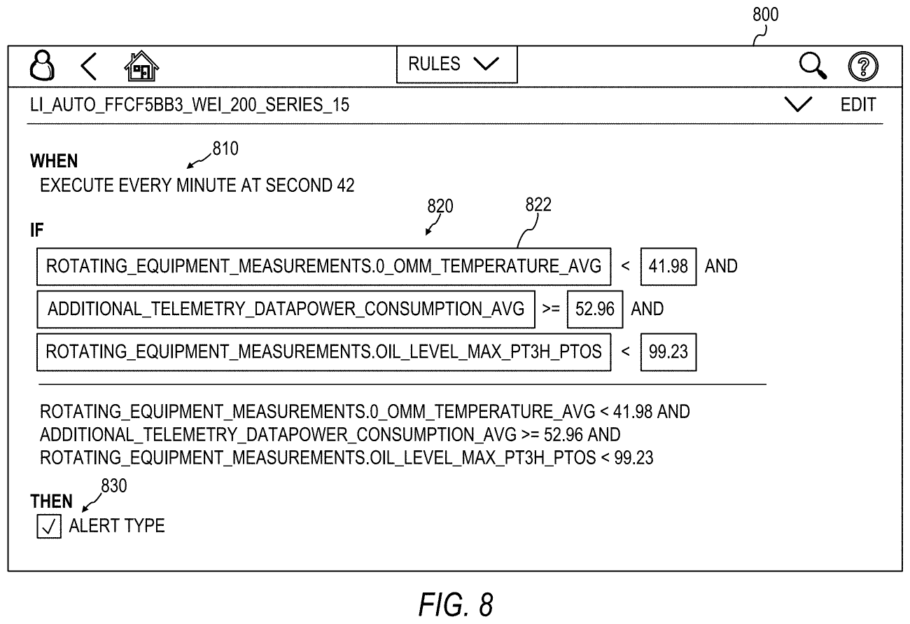

In some example embodiments, the analytics module 320 is configured to enable the user to submit input defining one or more alert rules for an equipment model. FIG. 8 illustrates a GUI 800 in which a user can submit input defining an alert rule for an equipment model, in accordance with some example embodiments. In FIG. 8, the GUI 800 shows an execution schedule 810 which may be configured by the user via one or more user interface elements. The execution schedule 810 specifies the timing for when the alert rule will be applied. The alert rule may be defined by a condition statement comprising an “if” portion and a “then” portion 830. The “if” portion 820 defines the condition(s) under which the “then” portion is to be performed, such as the condition(s) that will trigger the generation and presentation (e.g., display) of an alert. The GUI 800 may include one or more user interface elements 822 configured to be used by the user to specify the condition(s) for the generation and presentation of the alert. For example, the user may enter values into the user interface elements 822, specifying the triggering condition for an alert for a specific equipment model to be when a temperature metric for the specific equipment model is less than a particular temperature value, a power consumption metric for the specific equipment model is equal to or above a particular power consumption value, and an oil level metric for the specific equipment model is less than a particular oil level value.

In some example embodiments, the analytics module 320 stores the alert rule in the database(s) 330 in association with the equipment model. The analytics module 320 may monitor one or more parameters that indicate whether the condition(s) of the alert rule are satisfied, and then generate an alert based on the condition(s) of the alert rule being satisfied. For example, the analytics module 320 may determine that the user-specified condition(s) will occur at a particular time based on the failure curve analytics previously discussed (e.g., oil level metric will drop to a particular level at a certain time or age of the equipment model), and then generate and display an alert at that determined time or at a predetermined amount of time preceding that particular time in order to give the end user advanced warning to address a predicted upcoming equipment failure. The alerts may be displayed in a GUI as part of an application for equipment maintenance or may be transmitted as a notification to an electronic destination associated with an end user, such as an e-mail to an e-mail address or a text message to a phone number. Other types of alerts are also within the scope of the present disclosure.

In some example embodiments, the analytics module 320 is configured to display one or more of the generated analytical data (e.g., probability of failure data, remaining useful life data) as part of an equipment list and/or map of different equipment showing the location of the different equipment. The analytics module 320 may generate intelligent recommendations, such as alerts, for the timing and type of maintenance that should be performed for a piece of equipment based on the generated analytical data, and may automatically schedule such maintenance, such as by automatically adding event entries into an electronic calendar.

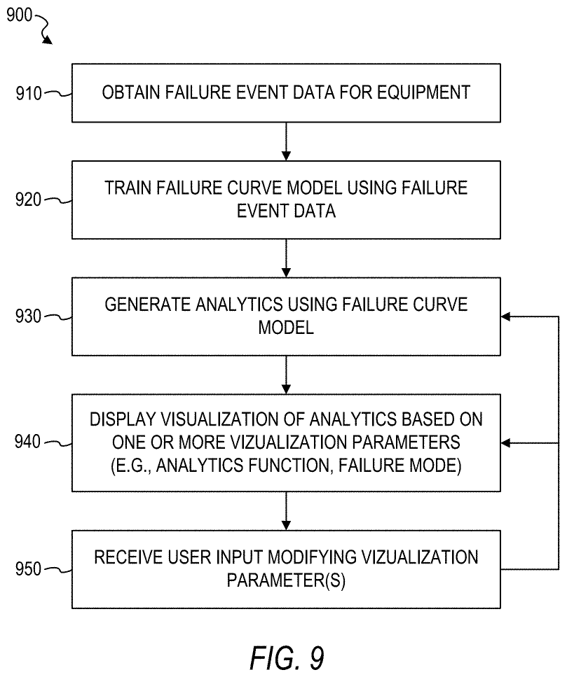

FIG. 9 is a flowchart illustrating a method of using failure curve analytics in an equipment maintenance system, in accordance with some example embodiments. The method 900 can be performed by processing logic that can comprise hardware (e.g., circuitry, dedicated logic, programmable logic, microcode, etc.), software (e.g., instructions run on a processing device), or a combination thereof. In one example embodiment, one or more of the operations of the method 900 are performed by the equipment maintenance system 300 of FIG. 3 or any combination of one or more of its modules 310 and 320. However, other implementations are also within the scope of the present disclosure.

At operation 910, the equipment maintenance system 300 obtains failure event data for an equipment model, as previously discussed. In some example embodiments, the failure event data identifies a plurality of events in which one or more physical instances of the equipment model suffered a functional failure. The failure data may be based on failure events for different physical instances of the same equipment model. For example, an organization may have multiple hydraulic pumps of the same model, and the equipment maintenance system 300 may collect and aggregate all of the data on the failure events for those multiple hydraulic pumps to form the failure data for that specific hydraulic pump model. In some example embodiments, the failure event data comprises corresponding failure mode data and corresponding time data for each event. The failure mode data may indicate a specific manner or way in which the physical instance of the equipment model failed for the corresponding event, and the time data may indicate a time at which the event occurred (e.g., date, time of day).

At operation 920, the equipment maintenance system 300 trains a failure curve model using the obtained failure event data. As previously discussed, the equipment maintenance system 300 may train the failure curve model by fitting the failure event data for the equipment model to a statistical and data driven model, such as one of the parametric, semi-parametric, or non-parametric models previously discussed. In some example embodiments, the failure curve model is configured to estimate corresponding lifetime failure data for the equipment model for each one of a plurality of different failure modes. The plurality of different failure modes correspond to different specific manners or ways in which the equipment model is capable of failing, and the lifetime failure data indicates a corresponding probability of the equipment model failing in the corresponding specific manner or way of the corresponding failure mode at any specific point in time during a lifetime of a physical instance of the equipment model.

At operation 930, the equipment maintenance system 300 generates analytical data for a failure mode of the plurality of failure modes for the equipment model using the failure curve model based on the failure mode. In some example embodiments, the analytical data indicates at least a portion of the lifetime failure data for the equipment model corresponding to the failure mode. For example, the equipment maintenance system 300 may generate probability of failure data or remaining useful life data using the failure curve model. Other types of analytical data are also within the scope of the present disclosure. In some example embodiments, the analytical data is generated for a failure mode of the plurality of failure modes.

In some example embodiments, the equipment maintenance system 300 accesses the failure curve model before using the failure curve model to generate the analytical data at operation 930. For example, subsequent to the training of the failure curve model at operation 920 and prior to the generating of the analytical data at operation 930, the trained failure curve model may be stored in a database, where it may then be accessed by the equipment maintenance system 300 for use in generating the analytical data at operation 930.

At operation 940, the equipment maintenance system 300 causes a visualization of the analytical data for the equipment model to be displayed. The visualization may be generated based on one or more visualization parameters, such as a type of analytics function (e.g., PoF, RUL), a particular failure mode, a specific user selected point on the visualization (e.g., a user selected point on a curve of a graph), a threshold level for a probability of failure for the equipment model, or a confidence interval value for the analytical data. In some example embodiments, the visualization of the analytical data comprises a graph indicating corresponding probabilities of failure by the corresponding specific manner or way of failing of the failure mode for the lifetime of the physical instance of the equipment model. However, other types of visualizations are also within the scope of the present disclosure.

At operation 950, the equipment maintenance system 300 may receive user input that modifies the visualization parameter(s) via one or more user interface elements. For example, the user may select a different analytics function for a different failure mode to be used for the visualization. The method 900 may then return to operation 940, where the equipment maintenance system 300 causes another visualization for the equipment model to be displayed based on the modified visualization parameter(s).

In another example, at operation 950, the equipment maintenance system 300 receives user input indicating another failure mode of the plurality of failure modes, and then returns to operation 930, where the equipment maintenance system 300 generates other analytical data for the other failure mode for the equipment model using the failure curve model based on the other failure mode. The equipment maintenance system 300 then causes a visualization of the other analytical data to be displayed on the computing device based on the receiving of the user input indicating the other failure mode, at operation 940. In some example embodiments, at operation 930, the equipment maintenance system 300 generates corresponding analytical data for each failure mode of the plurality of failure modes for the equipment model using the failure curve model prior to receiving the user input indicating any one of the failure modes at operation 950, thereby allowing the equipment maintenance system 300 to simply select the corresponding analytical data for the indicated failure mode after receiving the user input at operation 950 and proceed directly to causing a visualization of the pre-generated analytical data for the newly-indicated failure mode to be displayed at operation 940.

In yet another example, the visualization of the analytical data comprises a graph indicating corresponding probabilities of failure by the corresponding specific manner or way of failing of the failure mode for the lifetime of the physical instance of the equipment model, and, at operation 950, the equipment maintenance system 300 may receive a user selection of a point on a curve of the graph. The curve may represent the probabilities of failure. The method 900 may then return to operation 940, where the equipment maintenance system 300 causes additional data that is specific to the point on the curve to be displayed based on the user selection of the point on the curve.

In yet another example, at operation 950, the equipment maintenance system 300 receives an indication of a threshold level for a probability of failure for the equipment model. The method 900 may then return to operation 930, where the equipment maintenance system 300 determines an estimated future age of the physical instance of the equipment model at which the physical instance of the equipment model will exceed the threshold level for the probability of failure based on the failure curve model, and then calculates a remaining useful life value for the physical instance of the equipment model based on a difference between the estimated future age of the physical instance of the equipment model and a current age of the physical instance of the equipment model. The equipment maintenance system 300 then causes an indication of the remaining useful life value for the physical instance of the equipment model to be displayed on the computing device, at operation 940. In some example embodiments, the determination of the estimated future age of the physical instance of the equipment model and the calculation of the remaining useful life value for the physical instance of the equipment model, at operation 930, may be performed prior to receiving the indication of the threshold level for the probability of failure at operation 950, thereby allowing the equipment maintenance system 300 to simply proceed directly to causing a visualization of the an indication of the remaining useful life value for the physical instance of the equipment model to be displayed at operation 940 after receiving the indication of the threshold at operation 950.

In yet another example, at operation 950, the equipment maintenance system 300 receives, from the computing device, an indication of a confidence interval value for the first analytical data. The method 900 may then return to operation 930, where the equipment maintenance system 300 determines an upper bound and a lower bound for the analytical data based on the indication of the confidence interval value for the analytical data. The equipment maintenance system 300 then causes visual representations of the upper bound and the lower bound to be displayed on the computing device concurrently with the visualization of the analytical data, at operation 940. In some example embodiments, the determination of the upper and lower bounds, at operation 930, may be performed prior to receiving the indication of the confidence interval value at operation 950, thereby allowing the equipment maintenance system 300 to simply proceed directly to causing a visualization of the upper and lower bounds to be displayed at operation 940 after receiving the indication of the indication of the confidence interval value at operation 950.

It is contemplated that any of the other features described within the present disclosure can be incorporated into the method 900.

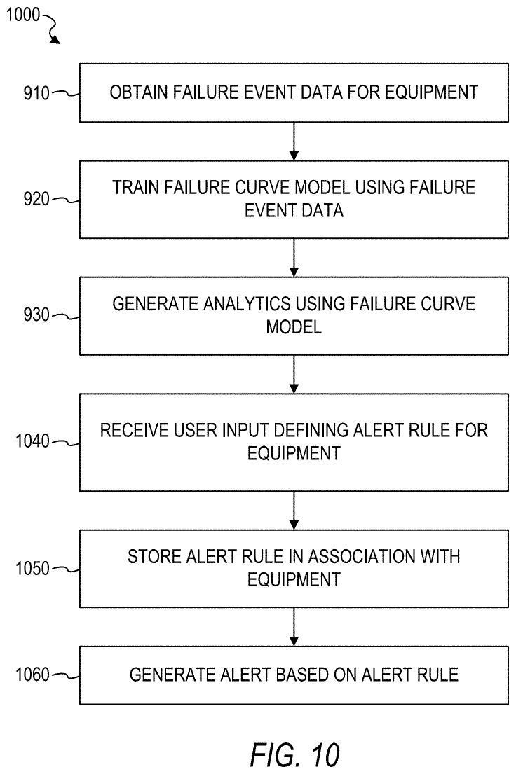

FIG. 10 is a flowchart illustrating another method of using failure curve analytics in an equipment maintenance system, in accordance with some example embodiments. The method 1000 can be performed by processing logic that can comprise hardware (e.g., circuitry, dedicated logic, programmable logic, microcode, etc.), software (e.g., instructions run on a processing device), or a combination thereof. In one example embodiment, one or more of the operations of the method 100 are performed by the equipment maintenance system 300 of FIG. 3 or any combination of one or more of its modules 310 and 320. However, other implementations are also within the scope of the present disclosure. The method 1000 may comprise operations 1040, 1050, and 1060 being performed subsequent to the performance of operations 910, 920, and 930 of the method 900 of FIG. 9.

At operation 1040, the equipment maintenance system 300 receives user input defining an alert rule for a physical instance of an equipment model from a computing device of a user. For example, the equipment maintenance system 300 may receive user input corresponding to one or more of an execution schedule (e.g., execution schedule 810 in FIG. 8) and a condition statement (e.g., “if” portion 820 and “then” portion 830 in FIG. 8) via one or more user interface elements. The condition statement may comprise one or more conditions that will trigger the generation of an alert based on a prediction of the one or more conditions being satisfied. At operation 1050, the equipment maintenance system 300 stores the alert rule defined by the received input in the database(s) 330 in association with the physical instance of the equipment model.

At operation 1060, the equipment maintenance system 300 generates and causes the presentation (e.g., the display) of an alert based on a determination that the condition(s) of the alert rule has been satisfied or will be satisfied within a threshold amount of time (e.g., the battery will die within the next 10 days). In some example embodiments, the equipment maintenance system 300 predicts that the condition(s) of the alert rule will be satisfied at a particular point in time based on the failure curve model, and then causes an alert notification to be displayed on the computing device of the user or on another computing device of another user at or before the particular point in time based on the prediction that the condition(s) of the alert rule will be satisfied. In one example where an alert rule comprises a single condition that the battery of an electrical machine dies, the equipment maintenance system 300 may predict that the battery of an electrical machine will die in 10 days, and the equipment maintenance system 300 may cause an alert notification to be displayed in 9 days based on the prediction, where the alert notification indicates the upcoming battery failure.

In some example embodiments, the equipment maintenance system 300 schedules a maintenance event in an electronic calendar in response to, or otherwise based on, the prediction that the condition(s) of the alert rule will be satisfied. The maintenance event may be scheduled for a time at or before the particular point in time of the predicted failure and may indicate a type of maintenance to be performed on the physical instance of the equipment model.

It is contemplated that any of the other features described within the present disclosure can be incorporated into the method 1000.

Certain embodiments are described herein as including logic or a number of components, modules, or mechanisms. Modules may constitute either software modules (e.g., code embodied on a machine-readable medium or in a transmission signal) or hardware modules. A hardware module is a tangible unit capable of performing certain operations and may be configured or arranged in a certain manner. In example embodiments, one or more computer systems (e.g., a standalone, client, or server computer system) or one or more hardware modules of a computer system (e.g., a processor or a group of processors) may be configured by software (e.g., an application or application portion) as a hardware module that operates to perform certain operations as described herein.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

Accordingly, the term “hardware module” should be understood to encompass a tangible entity, be that an entity that is physically constructed, permanently configured (e.g., hardwired) or temporarily configured (e.g., programmed) to operate in a certain manner and/or to perform certain operations described herein. Considering embodiments in which hardware modules are temporarily configured (e.g., programmed), each of the hardware modules need not be configured or instantiated at any one instance in time. For example, where the hardware modules comprise a general-purpose processor configured using software, the general-purpose processor may be configured as respective different hardware modules at different times. Software may accordingly configure a processor, for example, to constitute a particular hardware module at one instance of time and to constitute a different hardware module at a different instance of time.

Hardware modules can provide information to, and receive information from, other hardware modules. Accordingly, the described hardware modules may be regarded as being communicatively coupled. Where multiple of such hardware modules exist contemporaneously, communications may be achieved through signal transmission (e.g., over appropriate circuits and buses that connect the hardware modules). In embodiments in which multiple hardware modules are configured or instantiated at different times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices and can operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods described herein may be at least partially processor-implemented. For example, at least some of the operations of a method may be performed by one or more processors or processor-implemented modules. The performance of certain of the operations may be distributed among the one or more processors, not only residing within a single machine, but deployed across a number of machines. In some example embodiments, the processor or processors may be located in a single location (e.g., within a home environment, an office environment or as a server farm), while in other embodiments the processors may be distributed across a number of locations.

The one or more processors may also operate to support performance of the relevant operations in a “cloud computing” environment or as a “software as a service” (SaaS). For example, at least some of the operations may be performed by a group of computers (as examples of machines including processors), these operations being accessible via a network (e.g., the network 114 of FIG. 1) and via one or more appropriate interfaces (e.g., APIs).

Example embodiments may be implemented in digital electronic circuitry, or in computer hardware, firmware, software, or in combinations of them. Example embodiments may be implemented using a computer program product, e.g., a computer program tangibly embodied in an information carrier, e.g., in a machine-readable medium for execution by, or to control the operation of, data processing apparatus, e.g., a programmable processor, a computer, or multiple computers.

A computer program can be written in any form of programming language, including compiled or interpreted languages, and it can be deployed in any form, including as a stand-alone program or as a module, subroutine, or other unit suitable for use in a computing environment. A computer program can be deployed to be executed on one computer or on multiple computers at one site or distributed across multiple sites and interconnected by a communication network.

In example embodiments, operations may be performed by one or more programmable processors executing a computer program to perform functions by operating on input data and generating output. Method operations can also be performed by, and apparatus of example embodiments may be implemented as, special purpose logic circuitry (e.g., a FPGA or an ASIC).

A computing system can include clients and servers. A client and server are generally remote from each other and typically interact through a communication network. The relationship of client and server arises by virtue of computer programs running on the respective computers and having a client-server relationship to each other. In embodiments deploying a programmable computing system, it will be appreciated that both hardware and software architectures merit consideration. Specifically, it will be appreciated that the choice of whether to implement certain functionality in permanently configured hardware (e.g., an ASIC), in temporarily configured hardware (e.g., a combination of software and a programmable processor), or a combination of permanently and temporarily configured hardware may be a design choice. Below are set out hardware (e.g., machine) and software architectures that may be deployed, in various example embodiments.

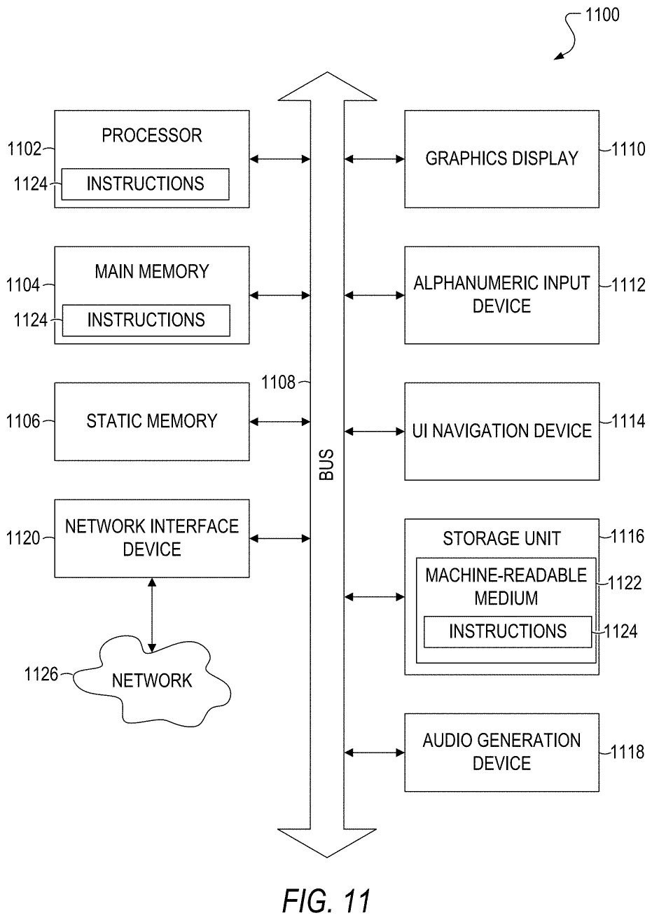

FIG. 11 is a block diagram of a machine in the example form of a computer system 1100 within which instructions 1124 for causing the machine to perform any one or more of the methodologies discussed herein may be executed. In alternative embodiments, the machine operates as a standalone device or may be connected (e.g., networked) to other machines. In a networked deployment, the machine may operate in the capacity of a server or a client machine in a server-client network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The example computer system 1100 includes a processor 1102 (e.g., a central processing unit (CPU), a graphics processing unit (GPU) or both), a main memory 1104, and a static memory 1106, which communicate with each other via a bus 1108. The computer system 1100 may further include a graphics or video display unit 1110 (e.g., a liquid crystal display (LCD) or a cathode ray tube (CRT)). The computer system 1100 also includes an alphanumeric input device 1112 (e.g., a keyboard), a user interface (UI) navigation (or cursor control) device 1114 (e.g., a mouse), a storage unit (e.g., a disk drive unit) 1116, an audio or signal generation device 1118 (e.g., a speaker), and a network interface device 1120.

The storage unit 1116 includes a machine-readable medium 1122 on which is stored one or more sets of data structures and instructions 1124 (e.g., software) embodying or utilized by any one or more of the methodologies or functions described herein. The instructions 1124 may also reside, completely or at least partially, within the main memory 1104 and/or within the processor 1102 during execution thereof by the computer system 1100, the main memory 1104 and the processor 1102 also constituting machine-readable media. The instructions 1124 may also reside, completely or at least partially, within the static memory 1106.

While the machine-readable medium 1122 is shown in an example embodiment to be a single medium, the term “machine-readable medium” may include a single medium or multiple media (e.g., a centralized or distributed database, and/or associated caches and servers) that store the one or more instructions 1124 or data structures. The term “machine-readable medium” shall also be taken to include any tangible medium that is capable of storing, encoding or carrying instructions for execution by the machine and that cause the machine to perform any one or more of the methodologies of the present embodiments, or that is capable of storing, encoding or carrying data structures utilized by or associated with such instructions. The term “machine-readable medium” shall accordingly be taken to include, but not be limited to, solid-state memories, and optical and magnetic media. Specific examples of machine-readable media include non-volatile memory, including by way of example semiconductor memory devices (e.g., Erasable Programmable Read-Only Memory (EPROM), Electrically Erasable Programmable Read-Only Memory (EEPROM), and flash memory devices); magnetic disks such as internal hard disks and removable disks; magneto-optical disks; and compact disc-read-only memory (CD-ROM) and digital versatile disc (or digital video disc) read-only memory (DVD-ROM) disks.

The instructions 1124 may further be transmitted or received over a communications network 1126 using a transmission medium. The instructions 1124 may be transmitted using the network interface device 1120 and any one of a number of well-known transfer protocols (e.g., HTTP). Examples of communication networks include a LAN, a WAN, the Internet, mobile telephone networks, POTS networks, and wireless data networks (e.g., WiFi and WiMax networks). The term “transmission medium” shall be taken to include any intangible medium capable of storing, encoding, or carrying instructions for execution by the machine, and includes digital or analog communications signals or other intangible media to facilitate communication of such software.

Each of the features and teachings disclosed herein can be utilized separately or in conjunction with other features and teachings to provide a system and method for blind spot implementation in neural networks. Representative examples utilizing many of these additional features and teachings, both separately and in combination, are described in further detail with reference to the attached figures. This detailed description is merely intended to teach a person of skill in the art further details for practicing certain aspects of the present teachings and is not intended to limit the scope of the claims. Therefore, combinations of features disclosed above in the detailed description may not be necessary to practice the teachings in the broadest sense, and are instead taught merely to describe particularly representative examples of the present teachings.

Some portions of the detailed descriptions herein are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the below discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present disclosure also relates to an apparatus for performing the operations herein. This apparatus may be specially constructed for the required purposes, or it may include a computer selectively activated or reconfigured by a computer program stored in the computer. Such a computer program may be stored in a computer readable storage medium, such as, but not limited to, any type of disk, including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, and each coupled to a computer system bus.

The example methods or algorithms presented herein are not inherently related to any particular computer or other apparatus. Various computer systems, computer servers, or personal computers may be used with programs in accordance with the teachings herein, or it may prove convenient to construct a more specialized apparatus to perform the method steps disclosed herein. The structure for a variety of these systems will appear from the description herein. It will be appreciated that a variety of programming languages may be used to implement the teachings of the disclosure as described herein.

Moreover, the various features of the representative examples and the dependent claims may be combined in ways that are not specifically and explicitly enumerated in order to provide additional useful embodiments of the present teachings. It is also expressly noted that all value ranges or indications of groups of entities disclose every possible intermediate value or intermediate entity for the purpose of original disclosure, as well as for the purpose of restricting the claimed subject matter. It is also expressly noted that the dimensions and the shapes of the components shown in the figures are designed to aid in understanding how the present teachings are practiced, but not intended to limit the dimensions and the shapes shown in the examples.

Although an embodiment has been described with reference to specific example embodiments, it will be evident that various modifications and changes may be made to these embodiments without departing from the broader spirit and scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

### EXAMPLES

1. A computer-implemented method comprising:
   accessing, by at least one hardware processor, a failure curve model for an equipment model, the failure curve model being configured to estimate corresponding lifetime failure data for the equipment model for each one of a plurality of different failure modes, the plurality of different failure modes corresponding to different specific manners or ways in which the equipment model is capable of failing, the lifetime failure data indicating a corresponding probability of the equipment model failing in the corresponding specific manner or way of the corresponding failure mode at any specific point in time during a lifetime of a physical instance of the equipment model;
   generating, by the at least one hardware processor, first analytical data for a first failure mode of the plurality of failure modes using the failure curve model based on the first failure mode, the first analytical data indicating at least a portion of the lifetime failure data for the equipment model corresponding to the first failure mode; and
   causing, by the at least one hardware processor, a visualization of the first analytical data to be displayed on a computing device.
2. The computer-implemented method of example 1, further comprising:
   generating, by the at least one hardware processor, second analytical data for a second failure mode of the plurality of failure modes using the failure curve model based on the second failure mode, the second analytical data indicating at least a portion of the lifetime failure data for the equipment model corresponding to the second failure mode, the second analytical data being different from the first analytical data, and the second failure mode being different from the first failure mode;
   receiving, by the at least one hardware processor from the computing device, user input indicating the second failure mode; and
   causing, by the at least one hardware processor, a visualization of the second analytical data to be displayed on the computing device based on the receiving of the user input indicating the second failure mode.
3. The computer-implemented method of example 1 or example 2, wherein the visualization of the first analytical data comprises a graph indicating corresponding probabilities of failure by the corresponding specific manner or way of failing of the first failure mode for the lifetime of the physical instance of the equipment model.
4. The computer-implemented method of any one of examples 1 to 3, further comprising:
   receiving, by the at least one hardware processor, a user selection of a point on a curve of the graph, the curve representing the probabilities of failure; and
   causing, by the at least one hardware processor, additional data that is specific to the point of the curve to be displayed based on the user selection of the point on the curve.
5. The computer-implemented method of any one of examples 1 to 4, further comprising:
   receiving, by the at least one hardware processor from the computing device, an indication of a threshold level for a probability of failure for the equipment model;
   determining, by the at least one hardware processor, an estimated future age of the physical instance of the equipment model at which the physical instance of the equipment model will exceed the threshold level for the probability of failure based on the failure curve model;
   calculating, by the at least one hardware processor, a remaining useful life value for the physical instance of the equipment model based on a difference between the estimated future age of the physical instance of the equipment model and a current age of the physical instance of the equipment model; and
   causing, by the at least one hardware processor, an indication of the remaining useful life value for the physical instance of the equipment model to be displayed on the computing device.
6. The computer-implemented method of any one of examples 1 to 5, further comprising:
   receiving, by the at least one hardware processor from the computing device, an indication of a confidence interval value for the first analytical data; and
   determining, by the at least one hardware processor, an upper bound and a lower bound for the first analytical data based on the indication of the confidence interval value for the first analytical data,
   wherein the causing the visualization of the first analytical data to be displayed on the computing device comprises causing visual representations of the upper bound and the lower bound to be displayed on the computing device concurrently with the visualization of the first analytical data.
7. The computer-implemented method of any one of examples 1 to 6, further comprising:
   receiving, by the at least one hardware processor from the computing device, user input defining an alert rule for the physical instance of the equipment model, the alert rule comprising at least one condition;
   storing, by the at least one hardware processor, the alert rule in a database in association with the physical instance of the equipment model;
   predicting, by the at least one hardware processor, that the at least one condition of the alert rule will be satisfied at a particular point in time based on the failure curve model; and
   causing, by the at least one hardware processor, an alert notification to be displayed on the computing device or on another computing device at or before the particular point in time based on the predicting that the at least one condition of the alert rule will be satisfied.
8. The computer-implemented method of any one of examples 1 to 7, further comprising scheduling, by the at least one hardware processor, a maintenance event into an electronic calendar based on the predicting that the at least one condition of the alert rule will be satisfied, the maintenance event being scheduled for a time at or before the particular point in time and indicating a type of maintenance to be performed on the physical instance of the equipment model.
9. The computer-implemented method of any of examples 1 to 8, further comprising:
   obtaining, by the at least one hardware processor, failure event data for the equipment model, the failure event data identifying a plurality of events in which one or more physical instances of the equipment model suffered a functional failure, the failure event data comprising corresponding failure mode data and corresponding time data for each event in the plurality of events, the failure mode data indicating a specific manner in which the one or more physical instances of the equipment model failed for the corresponding event, and the time data indicating a time at which the event occurred; and
   training, by the at least one hardware processor, the failure curve model for the equipment model using the failure event data for the equipment model.
10. A system comprising:
   at least one processor; and
   a non-transitory computer-readable medium storing executable instructions that, when executed, cause the at least one processor to perform the method of any one of examples 1 to 9.
11. A non-transitory machine-readable storage medium, tangibly embodying a set of instructions that, when executed by at least one processor, causes the at least one processor to perform the method of any one of examples 1 to 9.
12. A machine-readable medium carrying a set of instructions that, when executed by at least one processor, causes the at least one processor to carry out the method of any one of examples 1 to 9.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A computer-implemented method comprising:
accessing, by at least one hardware processor, a failure curve model for an equipment model, the failure curve model being configured to estimate corresponding lifetime failure data for the equipment model for each one of a plurality of different failure modes, the plurality of different failure modes corresponding to different specific manners in which the equipment model is capable of failing, the lifetime failure data indicating a corresponding probability of the equipment model failing in the corresponding specific manner of the corresponding failure mode at any specific point in time during a lifetime of a physical instance of the equipment model;
generating, by the at least one hardware processor, first analytical data for a first failure mode of the plurality of failure modes using the failure curve model based on the first failure mode, the first analytical data indicating at least a portion of the lifetime failure data for the equipment model corresponding to the first failure mode; and
causing, by the at least one hardware processor, a visualization of the first analytical data to be displayed on a computing device.

2. The computer-implemented method of claim 1, further comprising:
generating, by the at least one hardware processor, second analytical data for a second failure mode of the plurality of failure modes using the failure curve model based on the second failure mode, the second analytical data indicating at least a portion of the lifetime failure data for the equipment model corresponding to the second failure mode, the second analytical data being different from the first analytical data, and the second failure mode being different from the first failure mode;
receiving, by the at least one hardware processor from the computing device, user input indicating the second failure mode; and
causing, by the at least one hardware processor, a visualization of the second analytical data to be displayed on the computing device based on the receiving of the user input indicating the second failure mode.

3. The computer-implemented method of claim 1, wherein the visualization of the first analytical data comprises a graph indicating corresponding probabilities of failure by the corresponding specific manner of failing of the first failure mode for the lifetime of the physical instance of the equipment model.

4. The computer-implemented method of claim 3, further comprising:
receiving, by the at least one hardware processor, a user selection of a point on a curve of the graph, the curve representing the probabilities of failure; and
causing, by the at least one hardware processor, additional data that is specific to the point of the curve to be displayed based on the user selection of the point on the curve.

5. The computer-implemented method of claim 1, further comprising:
receiving, by the at least one hardware processor from the computing device, an indication of a threshold level for a probability of failure for the equipment model;
determining, by the at least one hardware processor, an estimated future age of the physical instance of the equipment model at which the physical instance of the equipment model will exceed the threshold level for the probability of failure based on the failure curve model;
calculating, by the at least one hardware processor, a remaining useful life value for the physical instance of the equipment model based on a difference between the estimated future age of the physical instance of the equipment model and a current age of the physical instance of the equipment model; and
causing, by the at least one hardware processor, an indication of the remaining useful life value for the physical instance of the equipment model to be displayed on the computing device.

6. The computer-implemented method of claim 1, further comprising:
receiving, by the at least one hardware processor from the computing device, an indication of a confidence interval value for the first analytical data; and
determining, by the at least one hardware processor, an upper bound and a lower bound for the first analytical data based on the indication of the confidence interval value for the first analytical data,
wherein the causing the visualization of the first analytical data to be displayed on the computing device comprises causing visual representations of the upper bound and the lower bound to be displayed on the computing device concurrently with the visualization of the first analytical data.

7. The computer-implemented method of claim 1, further comprising:
receiving, by the at least one hardware processor from the computing device, user input defining an alert rule for the physical instance of the equipment model, the alert rule comprising at least one condition;
storing, by the at least one hardware processor, the alert rule in a database in association with the physical instance of the equipment model;
predicting, by the at least one hardware processor, that the at least one condition of the alert rule will be satisfied at a particular point in time based on the failure curve model; and
causing, by the at least one hardware processor, an alert notification to be displayed on the computing device or on another computing device at or before the particular point in time based on the predicting that the at least one condition of the alert rule will be satisfied.

8. The computer-implemented method of claim 7, further comprising scheduling, by the at least one hardware processor, a maintenance event into an electronic calendar based on the predicting that the at least one condition of the alert rule will be satisfied, the maintenance event being scheduled for a time at or before the particular point in time and indicating a type of maintenance to be performed on the physical instance of the equipment model.

9. The computer-implemented method of claim 1, further comprising:
obtaining, by the at least one hardware processor, failure event data for the equipment model, the failure event data identifying a plurality of events in which one or more physical instances of the equipment model suffered a functional failure, the failure event data comprising corresponding failure mode data and corresponding time data for each event in the plurality of events, the failure mode data indicating a specific manner in which the one or more physical instances of the equipment model failed for the corresponding event, and the time data indicating a time at which the event occurred; and
training, by the at least one hardware processor, the failure curve model for the equipment model using the failure event data for the equipment model.

10. A system comprising:
at least one hardware processor; and
a non-transitory computer-readable medium storing executable instructions that, when executed, cause the at least one processor to perform operations comprising:
accessing a failure curve model for an equipment model, the failure curve model being configured to estimate corresponding lifetime failure data for the equipment model for each one of a plurality of different failure modes, the plurality of different failure modes corresponding to different specific manners in which the equipment model is capable of failing, the lifetime failure data indicating a corresponding probability of the equipment model failing in the corresponding specific manner of the corresponding failure mode at any specific point in time during a lifetime of a physical instance of the equipment model;
generating first analytical data for a first failure mode of the plurality of failure modes using the failure curve model based on the first failure mode, the first analytical data indicating at least a portion of the lifetime failure data for the equipment model corresponding to the first failure mode; and
causing a visualization of the first analytical data to be displayed on a computing device.

11. The system of claim 10, wherein the operations further comprise:
generating second analytical data for a second failure mode of the plurality of failure modes using the failure curve model based on the second failure mode, the second analytical data indicating at least a portion of the lifetime failure data for the equipment model corresponding to the second failure mode, the second analytical data being different from the first analytical data, and the second failure mode being different from the first failure mode;
receiving, from the computing device, user input indicating the second failure mode; and
causing a visualization of the second analytical data to be displayed on the computing device based on the receiving of the user input indicating the second failure mode.

12. The system of claim 10, wherein the visualization of the first analytical data comprises a graph indicating corresponding probabilities of failure by the corresponding specific manner of failing of the first failure mode for the lifetime of the physical instance of the equipment model.

13. The system of claim 12, wherein the operations further comprise:
receiving a user selection of a point on a curve of the graph, the curve representing the probabilities of failure; and
causing additional data that is specific to the point of the curve to be displayed based on the user selection of the point on the curve.

14. The system of claim 10, wherein the operations further comprise:
receiving, from the computing device, an indication of a threshold level for a probability of failure for the equipment model;
determining an estimated future age of the physical instance of the equipment model at which the physical instance of the equipment model will exceed the threshold level for the probability of failure based on the failure curve model;
calculating a remaining useful life value for the physical instance of the equipment model based on a difference between the estimated future age of the physical instance of the equipment model and a current age of the physical instance of the equipment model; and
causing an indication of the remaining useful life value for the physical instance of the equipment model to be displayed on the computing device.

15. The system of claim 10, wherein the operations further comprise:
receiving, from the computing device, an indication of a confidence interval value for the first analytical data; and
determining an upper bound and a lower bound for the first analytical data based on the indication of the confidence interval value for the first analytical data,
wherein the causing the visualization of the first analytical data to be displayed on the computing device comprises causing visual representations of the upper bound and the lower bound to be displayed on the computing device concurrently with the visualization of the first analytical data.

16. The system of claim 10, wherein the operations further comprise:
receiving, from the computing device, user input defining an alert rule for the physical instance of the equipment model, the alert rule comprising at least one condition;
storing the alert rule in a database in association with the physical instance of the equipment model;
predicting that the at least one condition of the alert rule will be satisfied at a particular point in time based on the failure curve model; and
causing an alert notification to be displayed on the computing device or on another computing device at or before the particular point in time based on the predicting that the at least one condition of the alert rule will be satisfied.

17. The system of claim 16, wherein the operations further comprise scheduling a maintenance event into an electronic calendar based on the predicting that the at least one condition of the alert rule will be satisfied, the maintenance event being scheduled for a time at or before the particular point in time and indicating a type of maintenance to be performed on the physical instance of the equipment model.

18. The system of claim 10, wherein the operations further comprise:
obtaining failure event data for the equipment model, the failure event data identifying a plurality of events in which one or more physical instances of the equipment model suffered a functional failure, the failure event data comprising corresponding failure mode data and corresponding time data for each event in the plurality of events, the failure mode data indicating a specific manner in which the one or more physical instances of the equipment model failed for the corresponding event, and the time data indicating a time at which the event occurred; and
training the failure curve model for the equipment model using the failure event data for the equipment model.

19. A non-transitory machine-readable storage medium, tangibly embodying a set of instructions that, when executed by at least one hardware processor, causes the at least one processor to perform operations comprising:
obtaining failure event data for an equipment model, the failure event data identifying a plurality of events in which one or more physical instances of the equipment model suffered a functional failure, the failure event data comprising corresponding failure mode data and corresponding time data for each event in the plurality of events, the failure mode data indicating a specific way in which the one or more physical instances of the equipment model failed for the corresponding event, and the time data indicating a time at which the event occurred;
training a failure curve model for the equipment model using the failure event data for the equipment model, the failure curve model being configured to estimate corresponding lifetime failure data for the equipment model for each one of a plurality of different failure modes, the plurality of different failure modes corresponding to different specific ways in which the equipment model is capable of failing, the lifetime failure data indicating a corresponding probability of the equipment model failing in the corresponding specific way of the corresponding failure mode at any specific point in time during a lifetime of a physical instance of the equipment model;
generating first analytical data for a first failure mode of the plurality of failure modes using the failure curve model based on the first failure mode, the first analytical data indicating at least a portion of the lifetime failure data for the equipment model corresponding to the first failure mode; and
causing a visualization of the first analytical data to be displayed on a computing device.

20. The non-transitory machine-readable storage medium of claim 19, wherein the operations further comprise:
generating second analytical data for a second failure mode of the plurality of failure modes using the failure curve model based on the second failure mode, the second analytical data indicating at least a portion of the lifetime failure data for the equipment model corresponding to the second failure mode, the second analytical data being different from the first analytical data, and the second failure mode being different from the first failure mode;
receiving, from the computing device, user input indicating the second failure mode; and
causing a visualization of the second analytical data to be displayed on the computing device based on the receiving of the user input indicating the second failure mode.
